(19) United States
(12) Patent Application Publication
(10) Pub. No.: US 2009/0272436 A1
(43) Pub. Date: Nov. 5, 2009

(54) NON-GLASS PHOTOVOLTAIC MODULE AND METHODS FOR MANUFACTURE

(76) Inventor: Osbert Hay Cheung, Concord, NC (US)

Correspondence Address: ADAMS INTELLECTUAL PROPERTY LAW, P.A., Suite 2350 Charlotte Plaza, 201 South College Street, CHARLOTTE, NC, 28244, US

(21) Appl. No.: 12/410,517

(22) Filed: Mar. 25, 2009

Related U.S. Application Data
(60) Provisional application No. 61/126,541, filed on May 5, 2008.

(51) Int. Cl. H01L 31/048; H01L 31/18

(52) U.S. Cl. 136/259; 438/64; 257/E31.001

(57) ABSTRACT

A non-glass photovoltaic module including a non-glass cover layer, a photovoltaic layer, a back protection sheet layer, and a support layer, wherein the layers are adhesively bonded together to form a lamination.

### CROSS-REFERENCE TO RELATED APPLICATIONS

This application claims priority to U.S. Provisional Application No. 61/126,541 filed May 5, 2008, and entitled “NON GLASS PHOTOVOLTAIC MODULE AND METHODS OF MAKING,” the contents of which are hereby incorporated by reference.

### FIELD OF THE INVENTION

The present invention relates to a photovoltaic module including a non-glass protective layer and methods for manufacture of the module.

### BACKGROUND OF THE INVENTION

Photovoltaic technology is considered to be a promising, clean energy source due to the utilization of the unlimited amount solar energy available without the harmful byproducts associated with nuclear energy and the combustion of fossil fuels and coal. In recent years, photovoltaic devices in the form of solar cells have become increasingly popular for supplying limited electrical power for domestic use and electrical equipment in remote or mobile locations where conventional sources of electricity are not readily available, and in the interest of conserving electrical power. More recently, photovoltaic energy has been viewed as a viable replacement, although in a limited sense, for the conventional production of electrical power, which has relied upon the use of fossil fuels and nuclear reactors. With regard to hydroelectric power generation, while considered an environmentally friendly method for producing electrical power, geographical limitations and cost prohibit this source from becoming a viable alternative for the purposes mentioned above.

Prior art photovoltaic materials and processes are extensive, and generally comprise layers of well known, commercially available materials assembled in a stacked arrangement to provide a photovoltaic element that encapsulates one or more or solar cells. The solar cells may be of a multi-crystalline or amorphous semiconductor, such as a silicone compound. Early conventional versions of photovoltaic elements employed a thin glass plate cemented to the outermost light-sensitive surface of the solar cell of the element by a suitable sealant resin. Photovoltaic elements today generally comprise a stack of layers and employ glass as a protective cover layer and an inert fluoropolymer as a backsheet to protect the element. Referring to prior art FIG. 2, a conventional glass solar module layout is shown generally at 200. The module includes a glass layer 202, solar cell 206 and a backsheet layer 208 arranged and bonded together with multiple adhesive layers 204. While glass is rigid and impermeable to moisture, therefore making it ideal as a structural support and weather covering for the solar cells, the use of glass plates present many inherent problems. Most notably, glass plates cannot be bent or cut to size, and with regard to tempered glass employed for its strength, it is also heavy and expensive if the glass is to be cut to different sizes for small quantity applications.

In building applications, photovoltaic modules are now being placed on rooftops and mounted to the surface of facades. With regard to installation, glass-type photovoltaic elements are typically attached to the facade material with mounting brackets in addition to the facade material itself. These arrangements not only increase cost, but also add weight that must be reinforced accordingly. In addition to weight, the application of glass-type photovoltaic elements tends to be limited by the method of manufacture of the elements. Since glass serves as the cover layer, the size of the module must be determined prior to the glass being tempered. Producing variable sizes of tempered glass is both costly and time consuming, and is one of the main challenges faced in the photovoltaic industry. Thus, utilizing glass as the cover layer prohibits large segments of photovoltaic materials, typically produced in large sheets, from being cut to size to conform to the installation site, for example, multi-angled surfaces, rooftop shapes, automotive and marine vessel rooftop shapes, and roadway support posts, among others. Another limitation to glass is that its fragile nature prevents it from being utilized with motion or as part of a moving body, such as with vehicles, marine vessels, and portable electrical equipment. In applications in which the glass cover breaks, because it functions not only as the cover layer but also as the support layer for the solar cells, inflexible solar cells will also break.

To overcome the inherent disadvantages of using glass as a cover layer, further developments in photovoltaic modules have been developed that utilize fluoropolymeric film as the covering material for weathering and environmental protection. The most common fluoropolymer films in use today include Tefzel, polyvinyl fluoride (PVF) and ethylene/tetrafluoroethylene (EFTE) coplymers. These film types are lightweight, flexible and inexpensive. Another popular copolymer film which functions as both an adhesive and a sealant is ethylene vinyl acetate (EVA), which can be cured and hardened after being heated to a high temperature such as to about 150 degrees C. While forming strong bonds between the substrates, EVA also prevents moisture from permeating to the photovoltaic cells. Other polylefin type resins include ethylene-methyl acrylate copolymer (EMA), ethylene-ethyl acrylate copolymer (EEA), and butyral resin, urethane resin, silicone, and the like.

A common back protection layer in use today is polyvinylidene fluoride film (PVF), sold under the Dupont Co. trademark, Tedlar®, which is used due to its weathering and protection qualities. However, as mentioned above, with regard to multi-layer flexible polymer film stacking to protect the solar cells, additional rigid reinforcing sheets are needed to support such a structure from distortion when crystalline solar cells are used. It is well known that other materials may be used as a reinforcing sheet, such as steel, aluminum, fiberglass-reinforced plastic (FRP), and the like. In addition, several methods have been disclosed for bonding the reinforced sheet to the photovoltaic element, with both the fluoropolymer film and Tedlar film adhering by EVA.

There are currently two processes for applying adhesives to substrates. The first includes utilizing high temperature adhesives, and the second includes utilizing low temperature adhesives. In the first process, the high temperature requires the use of EVA or similar polymeric material to form bonds during the heating process. When a stacked arrangement employs a reinforced plate such as fiberglass, aluminum or galvanized steel, the method of bonding the Tedlar layer and the reinforced plate is accomplished by adding an EVA layer between them, and then, heating to high temperature.

A problem with the high temperature method is that the reinforced material must be tolerant to the high temperature during the adhering process. Because of this, many rigid, lightweight, low cost reinforcing materials cannot be used with this method. Only a few rigid materials may be used, such as aluminum, steel, FRPs, carbon fiber, and like materials. Alternatively, the low temperature adhesive method is able to adhere a photovoltaic device to a reinforcing plate at room temperature. However, when a rubberized asphalt-type adhesive is used for such an application, asphalt becomes soft at high temperatures and brittle at low temperatures, making the material suitable only on flat rooftops or those with a very slight slope. When mounted at a steep angle or vertically, the module may slide or become dislodged at high temperatures.

Referring to prior art FIG. 3, a conventional non-glass solar module arrangement is shown generally at 300. The module includes a plastic film (ETFE) protection layer 302, solar cells 306 and a backsheet protection layer 308, secured together with multiple adhesive protection layers (EVA) 304. The module further includes a substrate panel 312 for supporting the module and providing rigidity adhered to the backsheet with an adhesive bonding agent 310. A disadvantage to this layered arrangement is that assembly requires a two-step process, wherein the first step 314 includes the adhesion of the plastic film, solar cells and backsheet with EVA being performed at a high temperature, such as about 140-150 degrees C. for about 15 minutes. Subsequently, the second step 316 includes the adhesion of the substrate panel at room temperature. The high temperature process, as stated above, for adhering the plastic film, solar cells and backsheet limits the type of substrate panel material, and requires additional time to process.

Referring to prior art FIG. 4, another example of a conventional non-glass module arrangement is shown generally at 400. The module includes a plastic film (ETFE) protection layer 402, solar cells 406 and a backsheet protection layer 408, secured together with multiple adhesive protection layers (EVA) 404. The module further includes a steel sheet 410 for rigidity and protection adhered with an adhesive layer (EVA) 404. The module further includes a substrate panel 414 for supporting the module and providing rigidity adhered to the backsheet with an adhesive bonding agent 412. A disadvantage to this layered arrangement is that assembly also requires a two-step process, wherein the first step 416 includes the adhesion of the plastic film, solar cells, backsheet and steel sheet with EVA being performed at a high temperature, such as about 140-150 degrees C. for about 15 minutes. Subsequently, the second step 418 includes the adhesion of the substrate panel at room temperature. The high temperature process, as stated above, for adhering the plastic film, solar cells and backsheet limits the type of substrate panel material, and requires additional time to process.

Accordingly, the present invention has been particularly devised to overcome the limitations and problems described in the foregoing, such limitations and problems including: the use of glass as the protective cover layer in a photovoltaic module concerning the lack of capability for “on-the-spot” customized installation design, flexibility, cost and weight; and the cumbersome and costly hardware generally used for mounting a module upon a final supporting structure at the installation site.

### SUMMARY OF THE INVENTION

In one aspect, a photovoltaic module is provided including a non-glass protective cover layer.

In another aspect, a photovoltaic module is provided including a photovoltaic layer including at least one, and preferably a plurality of photovoltaic cells.

In yet another aspect, a photovoltaic module is provided including a support layer for imparting rigidity to the module to prevent bending and cracking.

In yet another aspect, a photovoltaic module is provided including a back protection sheet layer for preventing leakage of electrical current to the environment.

In yet another aspect, a photovoltaic module is provided including at least one adhesive layer for the adhesion of the layers of the module together.

In yet another aspect, the layers of the photovoltaic module are bonded by heat activated bonding.

In yet another aspect, the photovoltaic module further includes a substrate panel adhered to the support layer by way of an adhesive.

In yet another aspect, a method for manufacturing a non-glass photovoltaic module is provided.

In yet another aspect, the method for manufacture is a single step process.

To achieve the foregoing and other aspects and advantages, and in accordance with the purposes of the invention as embodied and broadly described herein, a non-glass photovoltaic module and methods for manufacture are provided herein. In one embodiment, the photovoltaic module is a stacked arrangement including a non-glass cover layer for protecting the photovoltaic module from environmental impact, a photovoltaic layer underlying the cover layer and including at least one photovoltaic cell for producing an electrical current, a back protection sheet layer underlying the photovoltaic layer for preventing leakage of electrical current, and a support layer underlying the back protection sheet layer for imparting rigidity to the photovoltaic module.

A first adhesive layer is disposed between the cover layer and the photovoltaic layer. A second adhesive layer is disposed between the photovoltaic layer and the back protection sheet layer. A third adhesive layer is disposed between the back protection sheet layer and the support layer.

In another embodiment, a method for manufacturing a non-glass photovoltaic module is provided including the steps of: providing a plurality of layers including a non-glass cover layer, a photovoltaic layer including at least one photovoltaic cell, a back protection sheet layer, a support layer, and first, second and third adhesive layers; arranging the back protection sheet layer on the support layer with a first adhesive layer disposed therebetween; arranging the photovoltaic layer on the back protection sheet layer with a second adhesive layer disposed therebetween; arranging the non-glass cover layer on the photovoltaic layer with a third adhesive layer disposed therebetween; and heating the arranged module to a predetermined temperature to bond the plurality of layers and form a lamination.

Additional features and advantages of the invention will be set forth in the detailed description which follows, and in part will be readily apparent to those skilled in the art from that description or recognized by practicing the invention as described herein. It is to be understood that both the foregoing general description and the following detailed description present various embodiments of the invention, and are intended to provide an overview or framework for understanding the nature and character of the invention as it is claimed. The accompanying drawings are included to provide a further understanding of the invention, and are incorporated in and constitute a part of this specification.

### BRIEF DESCRIPTION OF THE DRAWINGS

Features, aspects and advantages of the present invention are understood when the following detailed description of the invention is read with reference to the accompanying drawings, in which:

FIG. 1 is a sectional view of a non-glass solar module layered arrangement in accordance with a preferred embodiment of the present invention;

FIG. 2 is a sectional view of a prior art glass solar module arrangement;

FIG. 3 is a sectional view of a prior art non-glass solar module arrangement including a substrate panel; and

FIG. 4 is a sectional view of a prior art non-glass solar module arrangement including a substrate panel and a steel sheet for providing rigidity.

### DETAILED DESCRIPTION OF THE INVENTION

The present invention will now be described more fully hereinafter with reference to the accompanying drawings in which exemplary embodiments of the invention are shown. However, the invention may be embodied in many different forms and should not be construed as limited to the representative embodiments set forth herein. The exemplary embodiments are provided so that this disclosure will be both thorough and complete, and will fully convey the scope of the invention and enable one of ordinary skill in the art to make, use and practice the invention.

Referring to the figure, a layered arrangement of a non-glass photovoltaic module is shown for providing the efficient transmission of sunlight upon one or more solar cells encapsulated within the module. The module further possesses the ability to remain in its originally processed position throughout the life of the module and is economical in manufacture and installation.

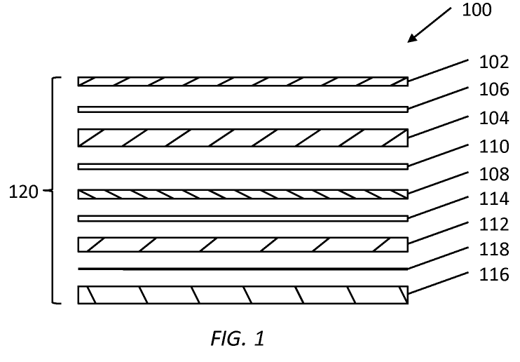

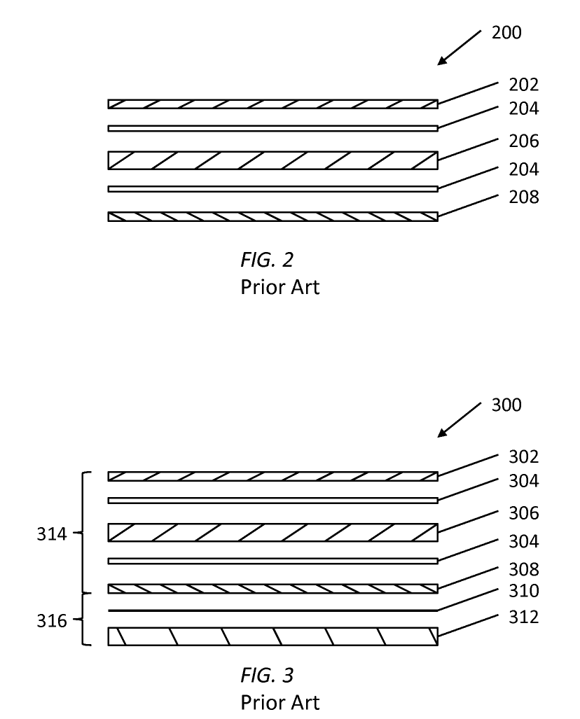

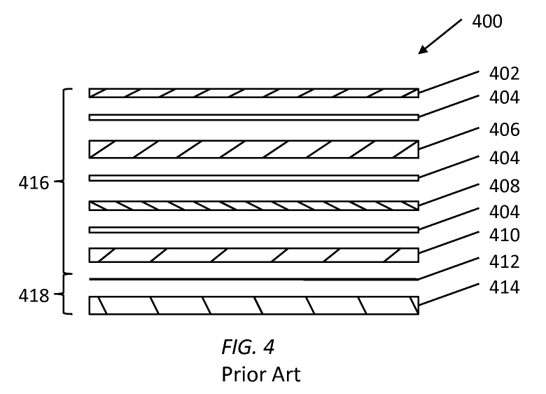

Referring now to FIG. 1, a sectional view of a preferred embodiment of a non-glass photovoltaic module is shown generally at reference numeral 100. The module includes a plurality of layers adhered or bonded together with layers of adhesive material to form a layered or stacked arrangement 120. The module includes a top, transparent, protective cover layer 102 adhesively arranged on an underlying photovoltaic layer 104. The cover layer 102 and photovoltaic layer 104 are adhered or bonded with a first adhesive layer 106 disposed between the layers. The cover layer 102 faces the sun and serves to protect the module 100 from exterior contaminants, weather conditions and physically applied damage. The underlying photovoltaic layer 104 includes at least one photovoltaic cell associated therewith for directly receiving sunlight and producing electrical current.

Suitable examples of protective cover layer materials include, but are not limited to, fluoropolymer films such as ethylene tetrafluoroethylene (ETFE), ethylene chlorofluoroethylene (ECTFE), perfluoro alkoxy, fluorinated ethylene propylene, polyvinylidene fluoride, tetrafluoroethylene hexafluoropropylene vinylidene fluoride, and other fluoropolymer materials such as Tefzel and polyvinyl fluoride (PVF). These types of preferred films are lightweight, flexible, inexpensive and have excellent performance results. The cover layer 102 may be optically transparent, possess a matte finish or possess a gloss finish. Each of the photovoltaic cells may be a mono-crystalline cell, multi-crystalline cell, amorphous silicon photovoltaic cell, or a compound semiconductor photovoltaic cell. Preferred photovoltaic cells of the module are of the multi-crystalline type due to cost and their ability to sustain a longer period in which to generate electricity. The plurality of photovoltaic cells are connected by suitable electrical conductors connected to a central electrical network, not forming a part of the invention. The cells are encapsulated within the module by the layers described herein. Photovoltaic cell size may vary and module size may vary. Exemplary cell sizes include, but are not limited to, 125 mm×125 mm, 156 mm×156 mm, and 210 mm×210 mm.

The photovoltaic module arrangement further includes the photovoltaic layer 104 adhesively arranged on a back protection sheet layer 108. The layers 104, 108 are bonded with a second adhesive layer 110 disposed between the layers. Adhesive layers 106 and 110, as well as additional adhesive layers described below are similar in material. The back protection sheet layer 108 functions to insulate the electrical current generated from the photovoltaic cells, protect the photovoltaic cells from environmental impact, and maintain the structural stability of the photovoltaic layer 104. A variety of materials have been utilized for back sheet protection layers, the most common of which includes polyfluoro polymers sold under the brand name Tedlar® by DuPont. Alternative materials include polyester polymers, and nylon-based and cotton-based films/sheets are also suitable for use in this application. Tedlar is preferred as it is chemically and UV-resistant. The back protection sheet layer 108 preferably has a thickness between about 0.002 inches and about 0.040 inches.

The back protection sheet layer 108 is further adhesively arranged on a support layer 112. The back protection sheet layer 108 and support layer are bonded through a third adhesive layer 114. The support layer 112 functions to increase rigidity and protect the photovoltaic cells from bending or cracking. The support layer 112 may include steel sheet or other metal or rigid material. The thickness of the support layer 112 preferably varies between about 0.005 inches and 0.40 inches, and more preferably is about 0.01 inches.

To provide further rigidity to the photovoltaic module and serve as a mounting structure, such as for rooftop mounting, for the photovoltaic module, the support layer 112 may optionally be adhesively arranged on a substrate panel layer 116. An adhesive layer 118 is disposed between the layers for adhesion of the layers. The adhesive layer 118 may be similar in material to the adhesive layers 106, 110 and 114, or may differ, such as a pressure-sensitive adhesive. The substrate panel layer 116 may include at least one of aluminum composite material, aluminum honeycomb, fiberglass reinforced plastic (FRP) and plastic sheet. The substrate panel layer 116 preferably has a thickness between about 0.125 inches and about 0.50 inches, and more preferably between about 0.25 inches or about 6 mm. The substrate panel layer 116 is preferably rigid to stand against 150 mph wind. Since the substrate panel layer is preferably made of a corrugated polymer as its core, its flutes can be used as either an air channel to cool the panel or a fluid channel as a hot water source.

The first, second and third adhesive layers 106, 110 and 114 (and optionally adhesive layer 118) function to encapsulate the photovoltaic cells and bond to hold layers 102, 104, 108 and 112 (and optionally layer 116) to form a unitary structure. The first, second and third adhesive layers preferably have a thickness of between about 0.001 inches and about 0.040 inches, and more preferably between about 0.015 inches to 0.030 inches. The first, second and third adhesive layers include at least one of a thermoplastic polyolefin, a thermoplastic polyurethane, a thermoplastic polyester and a thermoplastic ionomer. The first, second and third adhesive layers preferably do not undertake polymerization process like ethylene vinyl acetate (EVA), and may be heated repeatedly.

Suitable examples of materials comprising the adhesive layers include, but are not limited to, heat-activated adhesives such as the copolymer film ethylene vinyl acetate (EVA), thermoplastic polymers such as XUS film from Dow Chemical, Surlyn® available from Ionomer, thermoplastic urethanes such as Baeyer's Dureflex®, and other polyolefin polymers such as ethylene-methyl acrylate copolymer (FMA), silicone resin, and the like. Thermoplastic materials have processing and storage advantages as compared to EVA, which is currently the most commonly used adhesive/sealant for photovoltaic cell encapsulation. EVA polymerizes and hardens after being heated to a high temperature (e.g. 140-150 degrees C.) while bonding with photovoltaic cells and other materials, and requires time to cure and vacuum pressure for processing. Thermoplastic materials, in general, have weak adhesion strength to polyfluoro polymers that make up the protective cover layer.

Assembly of the photovoltaic module 100 occurs through heating and pressure, such as a pressure between about 12 lbs/sq. inch and about 15 lbs/sq. inch.

The method of manufacturing the non-glass photovoltaic module 100 includes: providing a plurality of layers including a non-glass cover layer, a photovoltaic layer including at least one photovoltaic cell, a back protection sheet layer, a support layer, and first, second and third adhesive layers; arranging the back protection sheet layer on the support layer with a first adhesive layer disposed therebetween; arranging the photovoltaic layer on the back protection sheet layer with a second adhesive layer disposed therebetween; arranging the non-glass cover layer on the photovoltaic layer with a third adhesive layer disposed therebetween; and heating the arranged module to a predetermined temperature to bond the plurality of layers and form a lamination.

While a non-glass photovoltaic module and methods for manufacture have been described with reference to specific embodiments and examples, it is envisioned that various details of the invention may be changed without departing from the scope of the invention. Furthermore, the foregoing description of the preferred embodiments of the invention and best mode for practicing the invention are provided for the purpose of illustration only and not for the purpose of limitation.

### Experimental Results

Experiment #1. The lamination of a 140 W solar panel having a panel size of approximately 42″×39″ was performed. ETFE film (5 mil) was laid out on a flat surface. A first layer of XUS film (15 mil) was applied on top of the ETFE film. Several strings cells were then laid on top of the XUS film. A second layer of XUS film was applied on top of the solar strings followed by an EPE (10 mil) layer, or a back protection sheet. The third layer of XUS film was applied on top of the back protection sheet. The substrate support panel was added last. The stacked layers of plastics, solar cells and substrate panel were placed into a laminator and underwent a lamination process at about 150 degrees C. for approximately 5 minutes and under 1 atmosphere of pressure (14.7 psi). The compressed solar panel was removed from the laminator after 5 minutes.

Experiment #2. The lamination of 90 W solar panels having a panel size of approximately 21.5″×47″ was performed. ETFE film (5 mil) was laid out on a flat surface. A first layer of XUS film (15 mil) was applied on top of the ETFE film. Several strings cells were then laid on top of the XUS film. A second layer of XUS film was applied on top of the solar strings followed by an EPE (10 mil) layer, or a back protection sheet. The third layer of XUS film was applied on top of the back protection sheet. A steel sheet (10 mil) was placed on top of the XUS film. The stacked layers of plastics, solar cells and steel sheet were placed into a laminator and underwent a lamination process at about 150 degrees C. for approximately 5 minutes and under 1 atmosphere pressure (14.7 psi). The compressed solar panel was removed from the laminator after 5 minutes.

What is claimed is:

1. A non-glass photovoltaic module, comprising:
a non-glass cover layer for protecting the photovoltaic module from environmental impact;
a photovoltaic layer underlying the cover layer and including at least one photovoltaic cell for producing an electrical current;
a back protection sheet layer underlying the photovoltaic layer for preventing leakage of electrical current;
a support layer underlying the back protection sheet layer for imparting rigidity to the photovoltaic module;
a first adhesive layer disposed between the cover layer and the photovoltaic layer;
a second adhesive layer disposed between the photovoltaic layer and the back protection sheet layer; and
a third adhesive layer disposed between the back protection sheet layer and the support layer.

2. The non-glass photovoltaic module according to claim 1, further comprising a substrate panel layer adhesively applied to the support layer.

3. The non-glass photovoltaic module according to claim 2, wherein the substrate panel layer comprises at least one of aluminum composite material, aluminum honeycomb and plastic sheet.

4. The non-glass photovoltaic module according to claim 1, wherein the first, second and third adhesive layers are heat-activated and bonding of the cover layer, photovoltaic layer, back protection sheet and support layer are bonded by heat activated bonding.

5. The non-glass photovoltaic module according to claim 1, wherein the first, second and third adhesive layers include at least one of a thermoplastic polyolefin, a thermoplastic polyurethane, a thermoplastic polyester and a thermoplastic ionomer.

6. The non-glass photovoltaic module according to claim 1, wherein the first, second and third adhesive layers have a higher melting point than ethylene vinyl acetate (EVA).

7. The non-glass photovoltaic module according to claim 1, wherein the back protection sheets layer includes material selected from the group consisting of: polyester, polyethylene tetraphthalate, nylon, cotton paper and bio-based polymer film.

8. The non-glass photovoltaic module according to claim 1, wherein the cover layer is made from a compound selected from the group consisting of: ethylene tetrafluoroethylene, perfluoro alkoxy, fluorinated ethylene propylene, tetrafluoroethylene/hexafluoropropylene/vinylidene fluoride, and polyvinylidene fluoride.

9. A method of manufacturing a non-glass photovoltaic module, comprising:
providing a plurality of layers including a non-glass cover layer, a photovoltaic layer including at least one photovoltaic cell, a back protection sheet layer, a support layer, and first, second and third adhesive layers;
arranging the back protection sheet layer on the support layer with a first adhesive layer disposed therebetween;
arranging the photovoltaic layer on the back protection sheet layer with a second adhesive layer disposed therebetween;
arranging the non-glass cover layer on the photovoltaic layer with a third adhesive layer disposed therebetween; and
heating the arranged module to a predetermined temperature to bond the plurality of layers and form a lamination.
